(19) United States
(12) Patent Application Publication
(10) Pub. No.: US 2024/0304769 A1
(43) Pub. Date: Sep. 12, 2024

(54) DISPLAY PANEL AND DISPLAY DEVICE

(71) Applicant: Tianma Advanced Display Technology Institute (Xiamen) Co., Ltd., Xiamen (CN)

(72) Inventors: Peixuan CHEN, Xiamen (CN); Meng WANG, Xiamen (CN)

(73) Assignee: Tianma Advanced Display Technology Institute (Xiamen) Co., Ltd., Xiamen (CN)

(21) Appl. No.: 18/666,104

(22) Filed: May 16, 2024

(30) Foreign Application Priority Data
Dec. 29, 2023 (CN) 202311873217.9

(51) Int. Cl. H01L 33/58; H01L 25/075; H01L 33/62

(52) U.S. Cl. CPC H01L 33/58; H01L 25/0753; H01L 33/62

(57) ABSTRACT

Provided are a display panel. The display panel includes a substrate, a light-emitting element, and a light control assembly. The light-emitting element is located on a side of the substrate. The light control assembly and the light-emitting element are on the same side of the substrate. The light control assembly includes a first light-shielding structure, a spacer structure, and a second light-shielding structure which are stacked. At least part of the first light-shielding structure surrounds the light-emitting element. The spacer structure is located on the side of the first light-shielding structure facing away from the substrate. The second light-shielding structure is located on the side of the spacer structure facing away from the first light-shielding structure. In a first direction, the maximum distance from the second light-shielding structure to the substrate is greater than or equal to the maximum distance from the light-emitting element to the substrate.

### CROSS-REFERENCE TO RELATED APPLICATION(S)

This application claims priority to Chinese Patent Application No. 202311873217.9 filed Dec. 29, 2023, the disclosure of which is incorporated herein by reference in its entirety.

### TECHNICAL FIELD

The present invention relates to the field of display technology and, in particular, to a display panel and a display device.

### BACKGROUND

With the continuous development of display technology, compared with organic light-emitting diode (OLED) display, micro light-emitting diode (microLED) display has advantages of high brightness, a wide color gamut, a long service life, and a fast response.

However, the microLED display still has many technical bottlenecks, and one of the bottlenecks is a halo. When a microLED transparent screen displays an image, light in a bright region may spread to a dark region, which causes the margin of the bright and dark dividing line of the display image to be unclear. As a result, the display effect is blurry, and the sense of sight is affected. There is an apparent halo, which affects the display quality of the image.

### SUMMARY

Embodiments of the present invention provide a display panel and a display device, so that a light control assembly can be configured to limit the light emitted by each light-emitting element. Thus, the halo phenomenon on a light emission side is reduced, and the display effect is improved.

In a first aspect, an embodiment of the present invention provides a display panel. The display panel includes a substrate, a light-emitting element, and a light control assembly. The light-emitting element is located on a side of the substrate. The light control assembly and the light-emitting element are on the same side of the substrate. The light control assembly includes a first light-shielding structure, a spacer structure, and a second light-shielding structure which are stacked. At least part of the first light-shielding structure surrounds the light-emitting element. The spacer structure is located on the side of the first light-shielding structure facing away from the substrate. The second light-shielding structure is located on the side of the spacer structure facing away from the first light-shielding structure. In a first direction, the maximum distance from the second light-shielding structure to the substrate is greater than or equal to the maximum distance from the light-emitting element to the substrate. The second light-shielding structure includes a first opening. In the first direction, the first opening at least partially overlaps the light-emitting element. The first direction is perpendicular to the plane where the substrate is located.

In a second aspect, an embodiment of the present invention provides a display device. The display device includes the display panel described above.

### BRIEF DESCRIPTION OF DRAWINGS

Features, advantages, and technical effects of example embodiments of the present invention may be described below with reference to the drawings.

FIG. 1 is a plan diagram of a display panel according to an embodiment of the present invention.

FIG. 2 is a diagram illustrating the structure of a display panel according to an embodiment of the present invention.

FIG. 3 is a diagram illustrating the structure of another display panel according to an embodiment of the present invention.

FIG. 4 is a diagram illustrating the structure of another display panel according to an embodiment of the present invention.

FIG. 5 is a diagram illustrating the structure of another display panel according to an embodiment of the present invention.

FIG. 6 is a plan diagram of another display panel according to an embodiment of the present invention.

FIG. 7 is a diagram illustrating the structure of another display panel according to an embodiment of the present invention.

FIG. 8 is a diagram illustrating the structure of another display panel according to an embodiment of the present invention.

FIG. 9 is a diagram illustrating the structure of another display panel according to an embodiment of the present invention.

FIG. 10 is a diagram illustrating the structure of another display panel according to an embodiment of the present invention.

FIG. 11 is a plan diagram of another display panel according to an embodiment of the present invention.

FIG. 12 is a diagram illustrating the structure of another display panel according to an embodiment of the present invention.

FIG. 13 is a diagram illustrating the structure of another display panel according to an embodiment of the present invention.

FIG. 14 is a diagram illustrating the structure of another display panel according to an embodiment of the present invention.

FIG. 15 is a diagram illustrating the structure of another display panel according to an embodiment of the present invention.

FIG. 16 is a diagram illustrating the structure of another display panel according to an embodiment of the present invention.

FIG. 17 is a diagram illustrating the structure of another display panel according to an embodiment of the present invention.

FIG. 18 is a diagram illustrating the structure of another display panel according to an embodiment of the present invention.

FIG. 19 is an optical principle diagram of a display panel according to an embodiment of the present invention.

FIG. 20 is an optical principle diagram of a display panel according to an embodiment of the present invention.

FIG. 21 is a diagram illustrating the structure of a display device according to an embodiment of the present invention.

### REFERENCE LIST

100 display panel
10 substrate
11 driver
20 light-emitting element
1 first opening
2 second opening
z first direction
AA first region
NA second region
30 light control assembly
31 first light-shielding structure
32 second light-shielding structure
33 third light-shielding structure
34 fourth light-shielding structure
35 fifth light-shielding structure
36 sixth light-shielding structure
37 spacer structure
37a first functional layer
37b second functional layer
37c third functional layer
38 first inorganic layer
39 first organic layer
40 light guide layer
50 color conversion structure
51 color conversion unit
52 black matrix
60 first filling layer
70 second filling layer
80 metal wire
90 encapsulation glass

In the drawings, like reference numerals refer to like components. The drawings are not drawn to actual scale.

### DETAILED DESCRIPTION

Features and example embodiments in various aspects of the present invention are described hereinafter in detail. In the detailed description below, numerous specific details are set forth to facilitate a thorough understanding of the present invention. However, to those skilled in the art, apparently, the present invention may be implemented with no need for some of these specific details. The description of the embodiments hereinafter is intended merely to provide a better understanding of the present invention through examples of the present invention. In the drawings and the description hereinafter, at least parts of the well-known structures and techniques are not shown to avoid unnecessary ambiguity to the present invention; moreover, the size of some structures may be exaggerated for clarity. The features, structures, or characteristics described hereinafter may be incorporated in one or more embodiments in any suitable manner.

The orientation words used in the description below refer to the directions shown in the figures and are not intended to limit the specific structures of the display panel and the display device in the present invention. In the description of the present invention, it is further to be noted that terms “mounted” and “connected” are to be understood in a broad sense unless otherwise expressly specified and limited. For example, the term “connected” may refer to “securely connected”, “detachably connected” or “integrally connected” or may refer to “connected directly” or “connected indirectly”. For those of ordinary skill in the art, specific meanings of the preceding terms in the present invention may be understood based on specific situations.

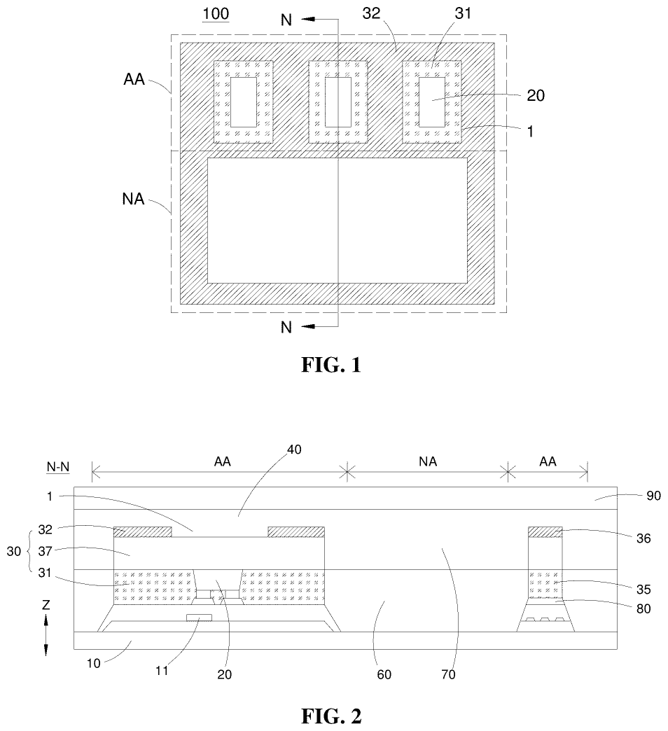

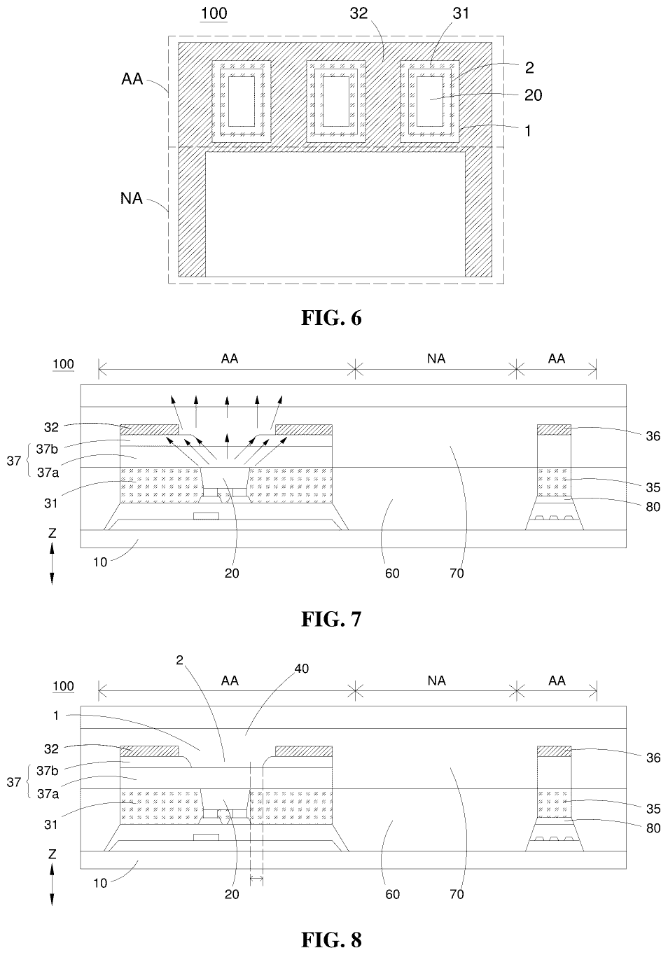

To better understand the present invention, the display panel and the display device according to the embodiments of the present invention are described below in detail with reference to FIG. 1 to FIG. 21.

Referring to FIGS. 1 and 2, an embodiment of the present invention provides a display panel 100. The display panel 100 includes a substrate 10, a light-emitting element 20, and a light control assembly 30. The light-emitting element 20 is located on a side of the substrate 10. The light control assembly 30 and the light-emitting element 20 are on the same side of the substrate 10. The light control assembly 30 includes a first light-shielding structure 31, a spacer structure 37, and a second light-shielding structure 32 which are stacked. At least part of the first light-shielding structure 31 surrounds the light-emitting element 20. The spacer structure 37 is located on the side of the first light-shielding structure 31 facing away from the substrate 10. The second light-shielding structure 32 is located on the side of the spacer structure 37 facing away from the first light-shielding structure 31. In a first direction Z, the maximum distance from the second light-shielding structure 32 to the substrate 10 is greater than or equal to the maximum distance from the light-emitting element 20 to the substrate 10. The second light-shielding structure 32 includes a first opening 1. In the first direction Z, the first opening 1 at least partially overlaps the light-emitting element 20. The first direction Z is perpendicular to the plane where the substrate 10 is located.

In an embodiment, the substrate 10 includes a glass baseplate and an array layer disposed on the glass baseplate. The light-emitting element 20 is specifically disposed on the array layer. The array layer can provide drive signals to multiple light-emitting elements 20 above, so that each light-emitting element 20 emits light according to a signal requirement.

Specifically, multiple drivers 11 are disposed on the array layer correspondingly connected to the light-emitting elements 20. Thus, specifically, a driver 11 in the array layer provides a drive signal to each light-emitting element 20. A driver 11 may use a thin-film transistor (TFT) device.

A light-emitting element 20 is specifically bonded to the substrate 10 so that the light-emitting element 20 is connected to the substrate 10. There are multiple bonding metals on the substrate 10. The light-emitting element 20 is connected to a corresponding bonding metal through the electrode of the light-emitting element 20. Multiple light-emitting elements 20 may be arranged in an array on the substrate 10.

In this embodiment, the light control assembly 30 is disposed around the light-emitting element 20. The light control assembly 30 specifically includes a first light-shielding structure 31, a spacer structure 37, and a second light-shielding structure 32. The first light-shielding structure 31 is disposed around the light-emitting element 20, and the main function of the first light-shielding structure 31 is to absorb the light emitted from the side of the light-emitting element 20, prevent the light emitted from the side from causing interference to adjacent components after scattering, and prevent this part of light from causing a halo phenomenon after being emitted from the top surface of the display panel 100 at the same time.

The spacer structure 37 is disposed on the first light-shielding structure 31, and the main function of the spacing structure 37 is to raise the second light-shielding structure 32. The second light-shielding structure 32 is disposed on the spacer structure 37 and formed with a first opening 1. The first opening 1 corresponds to the top surface of the light-emitting element 20 to ensure that light from the top surface can be emitted through the first opening 1.

In the first direction Z, the second light-shielding structure 32 is disposed around the light-emitting element 20, so that the second light-shielding structure 32 is used to shield the large viewing angle light of the light-emitting element 20. Thus, positive viewing angle light is emitted from the first opening 1. In this manner, not only normal light emission is ensured, but also the halo phenomenon at a large viewing angle is alleviated.

In an embodiment, the first light-shielding structure 31 and the second light-shielding structure 32 may be made of black adhesive materials. To ensure smooth emission of light from the light-emitting element 20, the spacer structure 37 between the two needs to be made of a transparent material, such as a transparent optical adhesive. The light emitted from the top surface of the light-emitting element 20 at a positive viewing angle is emitted from the first opening 1 after being transmitted by the spacer structure 37, and the other part of the large view angle light is absorbed by the second light-shielding structure 32.

During the formation of the process, the first light-shielding structure 31 is formed around the light-emitting element 20 to prevent the first light-shielding structure 31 from overflowing to the top surface when the first light-shielding structure 31 is higher than the top surface of the light-emitting element 20 and prevent the light emitted from the light-emitting element 20 from shielding. The first light-shielding structure 31 on the top surface is usually made of a black material and is not easily etched and removed. Thus, the spacer structure 37 is formed on the first light-shielding structure 31. At the same time, the light transmittance of the spacer structure 37 is used to ensure that light is exported.

After the spacer structure 37 is formed, the second light-shielding structure 32 is formed on the spacer structure 37, so that the second light-shielding structure 32 continues to shield large viewing angle light. At the same time, the corresponding position of the second light-shielding structure 32 and the light-emitting element 20 needs to be etched to form the first opening 1 to ensure light emitted at a positive viewing angle. Thus, the intermediate spacer structure 37 is used to make a light-shielding structure discontinuous. In this manner, a halo is alleviated, and the formation of the process is facilitated.

In an embodiment, when the maximum distance from the second light-shielding structure 32 to the substrate 10 is equal to the maximum distance from the light-emitting element to the substrate 10, that is, the top surface of the second light-shielding structure 32 is flush with the top surface of the light-emitting element 20, the second light-shielding structure 32 is disposed around the sidewall of the light-emitting element 20. The second light-shielding structure 32 may also be used to shield the light emitted from the side of the light-emitting element 20, thereby absorbing part of the light at a large viewing angle and alleviating the halo phenomenon.

In the display panel 100 provided by this embodiment of the present invention, the light control assembly 30 is disposed around the light-emitting element 20. The first light-shielding structure 31 in the light control assembly 30 is disposed around the light-emitting element 20 so that the light emitted from the side of the light-emitting element 20 is absorbed. At the same time, the spacer structure 37 in the light control assembly 30 is disposed on the first light-shielding structure 31, and the second light-shielding structure 32 is disposed on the spacer structure 37. The spacing structure 37 is used to raise the second light-shielding structure 32, so that the second light-shielding structure 32 absorbs the light emitted from the light-emitting element 20 at a large viewing angle. The first opening 1 in the second light-shielding structure 32 corresponds to the light-emitting element 20 to ensure that light at a positive viewing angle is emitted from the first opening 1. In this manner, the first light-shielding structure 31 may be used to absorb the side light of the light-emitting element 20, and the spacer structure 37 may be used to raise the second light-shielding structure 32 so that the second light-shielding structure 32 absorbs the large viewing angle light from the top surface of the light-emitting element 20. Thus, a halo phenomenon caused by the large viewing angle light of the light-emitting element 20 around the light-emitting element 20 is alleviated, blurry display is avoided, and the display effect is improved. At the same time, the spacing structure 37 is used to raise the second light-shielding structure 32. It is beneficial to the formation of the process, and a light-shielding structure is prevented from shielding the top surface of the light-emitting element 20 during the process, thereby facilitating the preparation of the light control assembly 30.

In an optional embodiment, referring to FIG. 2, the display panel 100 also includes a light guide layer 40 located on the side of the second light-shielding structure 32 facing away from the spacer structure 37. At least part of the light guide layer 40 is filled in the first opening 1.

In an embodiment, the light guide layer 40 is disposed on the second light-shielding structure 32 and partially filled in the first opening 1. The light guide layer 40 has the same light transmittance as the spacer structure 37, so that light emitted from the first opening 1 passes through the light guide layer 40 and then is emitted.

In an embodiment, the light guide layer 40 may be made of a transparent optical adhesive material. After the second light-shielding structure 32 is formed and etched to form the first opening 1, the light guide layer 40 is formed on the second light-shielding structure 32. Then, the light guide layer 40 may be connected to encapsulation glass 90 to form a final display panel 100 structure.

This embodiment of the present invention provides a display panel 100. The light guide layer 40 is disposed on the second light-shielding structure 32. The transparent characteristic of the light guide layer 40 is used to enable light of the light-emitting element 20 to be guided by the light guide layer 40 and then emitted, thereby providing conduct divergence space for light. At the same time, the light guide layer 40 is also used to facilitate the connection to the encapsulation glass 90.

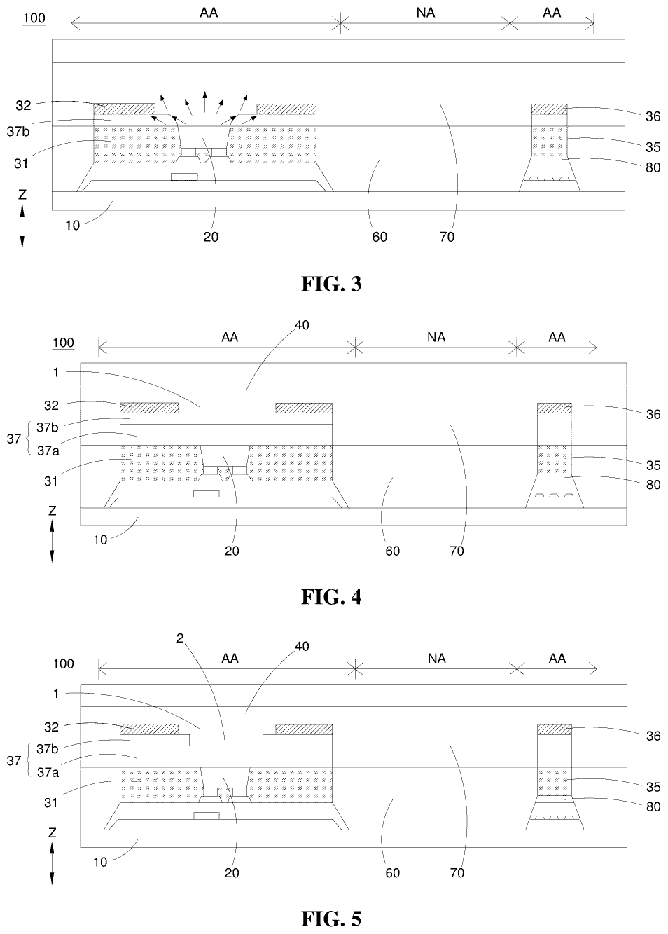

In an optional embodiment, referring to FIGS. 3 to 6, the spacer structure 37 includes a first functional layer 37a. In the first direction Z, the first functional layer 37a covers the light-emitting element 20. The first functional layer 37a and the light guide layer 40 include the same material.

For the specific film composition of the spacer structure 37, the spacer structure 37 may include a first functional layer 37a. The first functional layer 37a plays the role of transmitting light and raising the second light-shielding structure 32.

Considering that when the first functional layer 37a is used to conduct the emitted light, to avoid refraction loss caused when the light is conducted between adjacent films, the first functional layer 37a and the light guide layer 40 may use the same light-transmissive material. The object is to ensure that the refractive index of the two is the same. Thus, the two may also use materials of different components but the same refractive index.

In this manner, the emitted light enters the light guide layer 40 after being conducted by the first functional layer 37a. The light does not refract at the interface between two films, thereby avoiding the loss of the light. Of course, considering the actual situation, the refractive index between the two films may be similar, which can also alleviate the refraction loss of the light.

When the formation of the spacer structure 37 is considered, a relatively large thickness of the spacer structure 37 is not conducive to forming. Thus, the spacer structure 37 may also be disposed in a structural form of multiple first functional layers 37a, so that each first functional layer 37a has a relatively thin thickness, thereby facilitating the formation of the spacer structure 37. The number of functional layers is set to satisfy the actual thickness requirement of the spacer structure 37, and the refractive index between adjacent functional layers needs to be equal or similar.

This embodiment of the present invention provides a display panel 100. The first functional layer 37a and the light guide layer 40 use the same material, so that the light may not suffer refraction loss when passing through the two films and may have higher light emission intensity. At the same time, the first functional layer 37a is used to control and adjust the thickness of the spacer structure 37, so that the formation of the process of the spacer structure 37 is facilitated.

In an optional embodiment, referring to FIGS. 3 to 6, the spacer structure 37 includes a second functional layer 37b. The second functional layer 37b includes a second opening 2. In the first direction Z, the second opening 2 at least partially overlaps the light-emitting element 20. At least part of the light guide layer 40 is filled in the second opening 2. The refractive index of the light guide layer 40 is n1, and the refractive index of the second functional layer 37b is n2, where |n1-n2|>0.

In an embodiment, the refractive index of the second functional layer 37b in the spacer structure 37 and the refractive index of the light guide layer 40 may be designed differentially. Moreover, the second opening 2 is disposed on the second functional layer 37b and corresponds to the light-emitting element 20, so that the second opening 2 may be used to adjust the light emitted from the light-emitting element 20.

In this embodiment, it is mainly considered that after the second light-shielding structure 32 is used to shield part of the large viewing angle light, the loss of light brightness may be caused. Thus, in this embodiment, the cooperation relationship between the second functional layer 37b and the light guide layer 40 is used to improve display brightness.

In an embodiment, the light guide layer 40 is partially filled in the second opening 2, so that the refractive index n1 of the light guide layer 40 is greater than the refractive index n2 of the second functional layer 37b. Thus, the light guide layer 40 and the second functional layer 37b jointly form a micro prism structure to implement light adjustment.

Specifically, after light is emitted through the second opening 2 of the second functional layer 37b, the light is appropriately converged by the second functional layer 37b having a lower refractive index, and then the light is diverged out of the first opening 1 by the light guide layer 40 having a relatively large refractive index. In this manner, the brightness of the light is improved.

This embodiment of the present invention provides a display panel 100. The second opening 2 is disposed on the second functional layer 37b, and the refractive index of the second functional layer 37b and the refractive index of the light guide layer 40 are designed differentially, thereby forming a light adjustment structure and implementing the convergence and divergence of light. Thus, it is beneficial to improve the display brightness of the panel, and the light shielding loss caused by the second light-shielding structure 32 is compensated. Further, the light effect is improved.

In an optional embodiment, referring to FIG. 7, in a second direction, the width of the second opening 2 gradually increases. The second direction is a direction in which the spacer structure 37 points to the second light-shielding structure 32. The width of the second opening 2 is the size of the second opening 2 in a direction parallel to the plane where the display panel 100 is located.

In an embodiment, the surface at the second opening 2 on the second functional layer 37b may use an inclined plane to facilitate light diffusion. The light is directly refracted and adjusted at the inclined surface. The disposition of the inclined plane causes the size of the second opening 2 to be gradually enlarged.

Considering the brightness adjustment of light and the actual process formation, the included angle between the inclined plane at the second opening 2 and the plane where the display panel 100 is located may be set to 70° to 85°.

This embodiment of the present invention provides a display panel 100. The second opening 2 is configured to be a structure of which the size gradually increases, so that it is conducive to diverging the emitted light, thereby facilitating the export of the light. Further, the display brightness is improved, and the light emission effect is improved.

In an optional embodiment, referring to FIG. 8, in the first direction Z, the first opening 1 covers the second opening 2. Moreover/Alternatively, in the first direction Z, the second opening 2 covers the light-emitting element 20.

To prevent the second light-shielding structure 32 from shielding the second functional layer 37b after dimming, the set size of the first opening 1 is greater than the set size of the second opening 2. Thus, after the light brightness is increased through the second opening 2, the light can be smoothly emitted from the first opening 1. The second light-shielding structure 32 only shields large viewing angle light.

At the same time, the size of the second opening 2 is appropriately greater than the size of the top surface of the light-emitting element 20, so that spacing is formed between the two. Different spacing values result in different light emission effects, which facilitates the emission and adjustment of the light from the top surface of the light-emitting element 20. The spacing between the second opening 2 and the light-emitting element 20 may be controlled according to different actual requirements to adjust the display brightness.

This embodiment of the present invention provides a display panel 100. The sizes of the first opening 1, the second opening 2, and the light-emitting element 20 are controlled. On the basis of ensuring that the first opening 1 is used to shield large viewing angle light, the light-emitting brightness can be smoothly improved through the second opening 2. Thus, the display light effect is improved, and the case where the brightness is relatively dark is avoided.

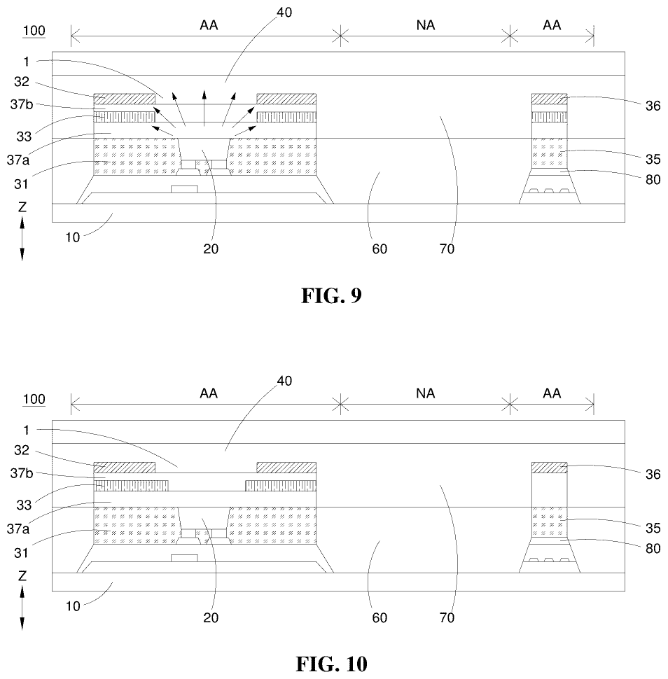

In an optional embodiment, referring to FIGS. 9 to 11, the spacer structure 37 includes a first functional layer 37a and a second functional layer 37b. In the first direction Z, the first functional layer 37a covers the light-emitting element 20. In the first direction Z, the second functional layer 37b is located on the side of the first functional layer 37a far away from the first light-shielding structure 31. A third light-shielding structure 33 is included between the first functional layer 37a and the second functional layer 37b. Moreover, in the first direction Z, the light-emitting element 20 and the third light-shielding structure 33 at least partially do not overlap.

When the spacer structure 37 includes two structures: the first functional layer 37a and the second functional layer 37b, the first functional layer 37a directly covers the light-emitting element 20 and at the same time raises the second functional layer 37b. In this embodiment, the third light-shielding structure 33 is further disposed between the first functional layer 37a and the second functional layer 37b, and large viewing angle light is further shielded.

At this time, the first functional layer 37a and the second functional layer 37b use transparent materials to ensure the smooth emission of light. The third light-shielding structure 33 between the two also shields large viewing angle light. Since the third light-shielding structure 33 is located below the second light-shielding structure 32, the light may be first absorbed by the third light-shielding structure 33, and the remaining large viewing angle light is continuously absorbed by the second light-shielding structure 32 after being missed.

It is to be understood that the third light-shielding structure 33 here absorbs the light at a large viewing angle for the first time. Then the second light-shielding structure 32 absorbs the remaining light for the second time. In this manner, double shielding is formed for the light at the large viewing angle, thereby further alleviating a halo phenomenon.

In an embodiment, different numbers of light-shielding structures and functional layers may be disposed according to different actual shielding requirements. A light-shielding structure is disposed between adjacent functional layers, so that multi-level light absorption is implemented for large viewing angle light, and more sufficient shielding is formed for the large viewing angle light.

This embodiment of the present invention provides a display panel 100. The third light-shielding structure 33 is disposed between the first functional layer 37a and the second functional layer 37b, so that the large viewing angle light is preliminarily shielded. Thus, the large viewing angle light is more fully absorbed, thereby further alleviating a halo phenomenon.

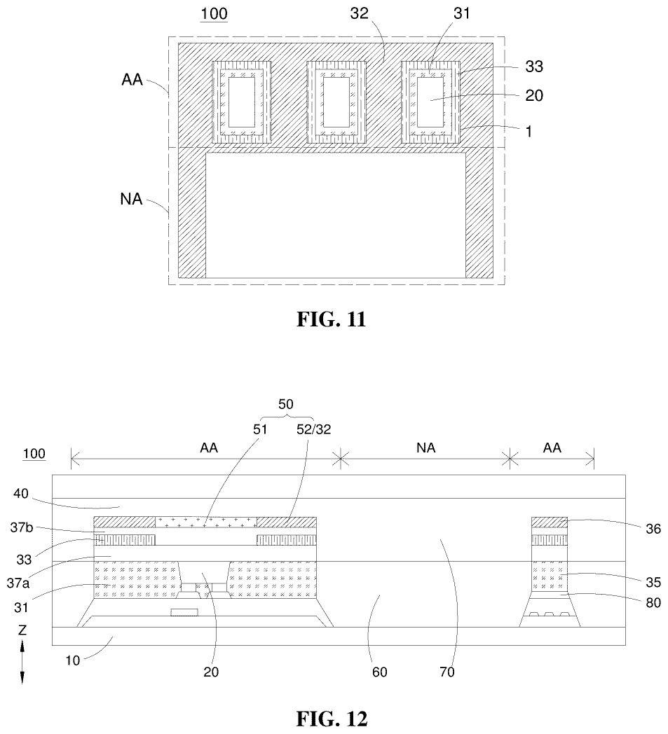

In an optional embodiment, referring to FIGS. 10 and 11, in a direction parallel to the direction of the display panel 100, the minimum distance from the third light-shielding structure 33 to the corresponding light-emitting element 20 is less than the minimum distance from the second light-shielding structure 32 to the corresponding light-emitting element 20.

The light-emitting element 20 corresponding to the second light-shielding structure 32 and the third light-shielding structure 33 here refers to the same light-emitting element 20. The second light-shielding structure 32 and the third light-shielding structure 33 at the same light-emitting element 20 have differences in size.

In an embodiment, the third light-shielding structure 33 may be disposed more adjacent to the light-emitting element 20 than the second light-shielding structure 32. Thus, after the light-emitting element 20 emits light, first, the large viewing angle light is preliminarily shielded by the third light-shielding structure 33, and then the remaining missed light is shielded by the second light-shielding structure 32, thereby completing the double absorption of light.

Of course, the sizes of different light-shielding structures may also be adjusted according to actual halo requirements. For example, the second light-shielding structure 32 may be configured to overlap the third light-shielding structure 33 in the first direction Z, which also has a relatively good shielding effect.

A part of light irradiated to the second light-shielding structure 32 is directly absorbed, but another part of the light may be reflected. At this time, this part reflected light may be absorbed by the third light-shielding structure 33 at the bottom. At the same time, light may also be reflected alternately between the two light-shielding structures. Thus, light at a large viewing angle gradually attenuates. In this manner, on the basis of alleviating a halo, the impact of the reflected light on the display panel 100 is also avoided.

This embodiment of the present invention provides a display panel 100. The sizes of the third light-shielding structure 33 and the second light-shielding structure 32 are designed differentially, so that double shielding of large viewing angle light is implemented, and a better guarantee is provided for alleviating the halo phenomenon.

In an optional embodiment, in the first direction Z, the thickness of the first functional layer 37a is greater than the thickness of the second functional layer 37b. Moreover/Alternatively, in the first direction Z, the thickness of the third light-shielding structure 33 is greater than the thickness of the second light-shielding structure 32.

In an embodiment, in the spacer structure 37, the thickness of the first functional layer 37a is greater than the thickness of the second functional layer 37b, so that the second functional layer 37b is raised. Thus, the overall thickness satisfies the thickness requirement of the spacer structure 37, which facilitates the formation of the process. At the same time, the thickness of the third light-shielding structure 33 is greater than the thickness of the second light-shielding structure 32, so that the third light-shielding structure 33 has a better light-shielding capacity, which facilitates the absorption of large viewing angle light. The thickness of each film is not particularly limited in the present invention and may be determined according to actual light-shielding requirements.

In an optional embodiment, referring to FIG. 12, the display panel 100 also includes a color conversion structure 50 located on the side of the second light-shielding structure 32 far away from the light-emitting element 20. The color conversion structure 50 includes multiple color conversion units 51. In the first direction Z, a color conversion unit 51 overlaps at least one light-emitting element 20.

Considering that the light-emitting element 20 has different light emission colors, the light-emitting element 20 has three colors of light: red, green, and blue light. Thus, the color conversion structure 50 may be disposed on the top surface of the light control assembly 30 to implement filtering and adjustment of the display panel 100 and implement color display of the display panel 100 after light mixing.

Specifically, the color conversion structure 50 is disposed on the second light-shielding structure 32, so that after the second light-shielding structure 32 is used to absorb large viewing angle light, the color conversion structure 50 is then used to filter the light. The color conversion structure 50 includes multiple color conversion units 51. The multiple color conversion units 51 can adjust the light to a required color.

In an embodiment, the color conversion unit 51 corresponds to the light-emitting element 20 to filter the light emitted from the light-emitting element 20. The color conversion unit 51 may be a quantum dot material. When the light from the light-emitting element 20 is irradiated to the color conversion unit 51, the color conversion unit 51 is excited to emit light of a corresponding color, and the color conversion process is completed.

Alternatively, the color conversion unit 51 may also use a color filter film structure. Similarly, light that passes through the color conversion unit 51 may be filtered to obtain light of a required color. The specific structure of the color conversion unit 51 is not specifically limited in the present invention.

For the color conversion structure 50, the structure also includes a black matrix 52. The black matrix 52 is disposed around each color conversion unit 51 to shield and absorb the remaining light during the light filtering process.

In an embodiment, in this embodiment, the black matrix 52 in the color conversion structure 50 may be stacked on the second light-shielding structure 32, or the second light-shielding structure 32 may also serve as the black matrix 52 to shield the light around the color conversion unit 51 and at the same time shield large viewing angle light to alleviate a halo phenomenon, as shown in FIG. 12.

This embodiment of the present invention provides a display panel 100. The color conversion structure 50 is disposed on the second light-shielding structure 32. After large viewing angle light is absorbed to alleviate a halo problem, the emitted light is filtered and adjusted. The color display of the panel is completed after light mixing, and the display effect is better. At the same time, the material of a light-shielding structure is saved.

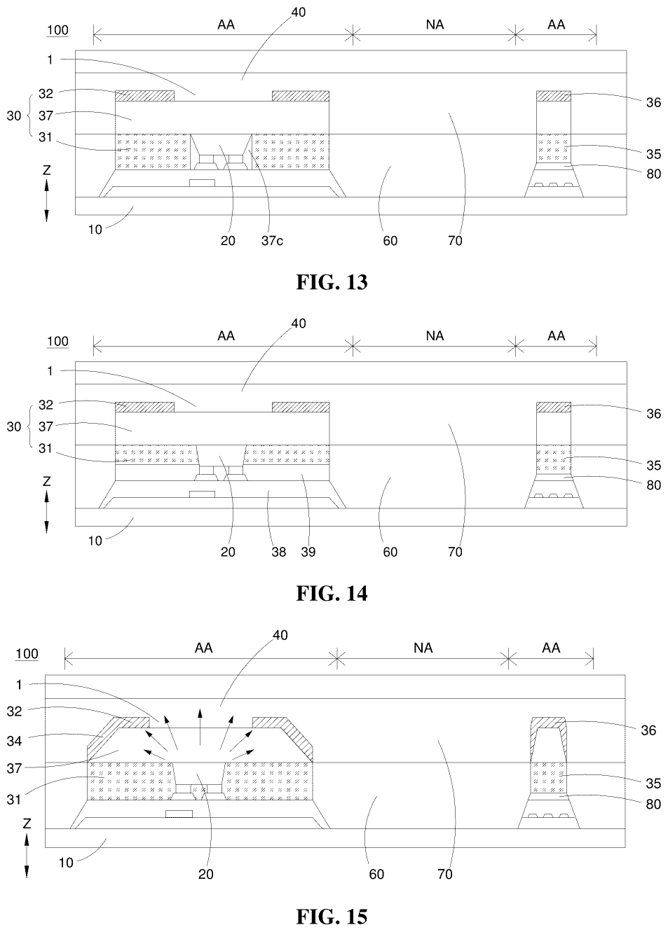

In an optional embodiment, referring to FIG. 13, in a direction parallel to the plane where the display panel 100 is located, a third functional layer 37c is comprised between the first light-shielding structure 31 and the light-emitting element 20.

In an embodiment, the third functional layer 37c is located between the light-emitting element 20 and the first light-shielding structure 31 and is also used as a transparent layer. The refractive index of the third functional layer 37c is less than the refractive index of the light-emitting element 20. At the same time, the light-emitting element 20 can cover the third functional layer 37c.

It is to be understood that in this embodiment, the third functional layer 37c may be the remained layer after the transparent layer around the light-emitting element 20 is etched. Since the light-emitting element 20 shields the etching process, the third functional layer 37c is located around the light-emitting element 20.

In this embodiment, the third functional layer 37c surrounds the light-emitting element 20. Due to the transparent attribute of the third functional layer 37c, the extraction of the light of the light-emitting element 20 can be facilitated. Part of the light passes through the third functional layer 37c and enters the upper spacer structure 37 to export the light.

In an embodiment, the refractive index of the light-emitting element 20 is far greater than the refractive index of the third functional layer 37c disposed around the light-emitting element 20. Thus, when the light-emitting element 20 emits light from a side, light of partial angles is totally reflected at a critical surface. Thus, part of the side light is reflected to the top surface, so that the display brightness at a positive viewing angle is increased, and utilization of light is improved.

This embodiment of the present invention provides a display panel 100. The third functional layer 37c is disposed between the first light-shielding structure 31 and the light-emitting element 20. On the basis of complying with the actual etching process, it is also conducive to exporting the side light of the light-emitting element 20. In this manner, the utilization of light is improved, the display brightness is further improved, and the display effect is better.

In an optional embodiment, referring to FIG. 14, in the first direction Z, a first inorganic layer 38 is included between the light-emitting element 20 and the substrate 10. A first organic layer 39 is included between the first inorganic layer 38 and the first light-shielding structure 31. In the first direction Z, the maximum distance from the first organic layer 39 to the substrate 10 is less than the minimum distance from the light-emitting layer of the light-emitting element 20 to the substrate 10.

In an embodiment, the first inorganic layer 38 and the first organic layer 39 are stacked between the light-emitting element 20 and the substrate 10. The first light-shielding structure 31 is disposed on the first organic layer 39 and surrounds the sidewall of the light-emitting element 20. The first inorganic layer 38 and the first organic layer 39 appropriately raise the first light-shielding structure 31.

Since the light-emitting element 20 may partially shield the etching process, the structure of the first organic layer 39, may be the remaining part at the position of the light-emitting element 20 during the process of etching the first filling layer 60. It can be seen that the first organic layer 39 and the first filling layer 60 use the same transparent material. Due to the existence of the first organic layer 39, there is no need to fully etch the light-emitting element 20. Thus, the etching time at the light-emitting element 20 is appropriately shortened, thereby improving the process preparation efficiency.

Specifically, the light-emitting element 20 mainly emits light through the light-emitting layer between the two electrodes. To prevent the light-emitting layer of the light-emitting element from emitting light toward the bottom of the light-emitting element 20 and causing interference to the array layer, the bottom surface of the first light-shielding structure 31 needs to be disposed under the light-emitting layer of the light-emitting element 20, so that the light from the light-emitting element 20 toward the bottom can be shielded.

That is, the top surface of the first organic layer 39 needs to be controlled to be at the bottom of the light-emitting layer in the light-emitting element 20, so that the first light-shielding structure 31 can be partially under the light-emitting layer, and the side light of the bottom of the light-emitting element 20 is shielded.

This embodiment of the present invention provides a display panel 100. The position relationship between the first organic layer 39 and the light-emitting layer of the light-emitting element 20 is controlled, so that the first light-shielding structure 31 can fully shield the side light of the light-emitting element 20 and prevent part of the side light from entering the array layer at the bottom and causing an adverse effect on signal driving. Thus, the entire display panel 100 is better shielded and protected.

In an optional embodiment, referring to FIG. 15, the display panel 100 includes a fourth light-shielding structure 34. In the direction parallel to the plane where the display panel 100 is located, the fourth light-shielding structure 34 at least partially overlaps the spacer structure 37.

Since the spacer structure 37 has light transmittance, when the light emitted from the light-emitting element 20 is conducted through the spacer structure 37, part of the light at a large viewing angle may be absorbed by the second light-shielding structure 32, and another part of the large viewing angle light may be emitted from the sidewall of the spacer structure 37. Thus, in this embodiment, the fourth light-shielding structure 34 is disposed at the spacer structure 37.

In an embodiment, when there are multiple layers of light-shielding structures in the light control assembly 30, a fourth light-shielding structure 34 may be disposed at a corresponding functional layer of a light-shielding structure of each layer. The fourth light-shielding structure 34 is used to perform light-shielding processing on the sidewall of each functional layer to prevent light from being emitted from an edge of the spacer structure 37 and causing light interference.

This embodiment of the present invention provides a display panel 100. The fourth light-shielding structure 34 is configured to overlap the spacer structure 37, so that light-shielding processing is performed on the spacer structure 37 to prevent part of the large viewing angle light from emitting from the spacer structure 37 and causing poor display. Thus, a better guarantee is provided for alleviating the halo.

In an optional embodiment, the second light-shielding structure 32 is in contact with and connected to the fourth light-shielding structure 34.

In an embodiment, the second light-shielding structure 32 and the fourth light-shielding structure 34 may be integrally formed, so that the entire structure is used as a continuous light-shielding structure and covers the spacer structure 37. The second light-shielding structure 32 may also be connected to the fourth light-shielding structure 34 to form a continuous light-shielding structure.

In an embodiment, the second light-shielding structure 32 covers the top surface of the spacer structure 37, and the fourth light-shielding structure 34 covers the side surface of the spacer structure 37, so that sufficient light shielding is performed on the spacer structure 37.

This embodiment of the present invention provides a display panel 100. The second light-shielding structure 32 is connected to the fourth light-shielding structure 34, so that the light-shielding structures form a continuous structure. Thus, light shielding is performed on the spacer structure 37. At the same time, it is beneficial to the formation of the light-shielding structure, and the completion of process preparation is facilitated.

In an optional embodiment, the included angle between the second light-shielding structure 32 facing the surface of the light-emitting element 20 and the fourth light-shielding structure 34 facing the surface of the light-emitting element 20 is greater than or equal to 90°.

Due to process characteristics, during the etching process of the spacer structure 37, the sidewall surface of the obtained spacer structure 37 is an inclined plane. Thus, the fourth light-shielding structure 34 adaptively covers and is adaptively attached to the inclined plane. A right angle or obtuse angle is formed between the fourth light-shielding structure 34 and the second light-shielding structure 32 on the top surface.

This embodiment of the present invention provides a display panel 100. The included angle between the second light-shielding structure 32 and the fourth light-shielding structure 34 is configured to be a right angle or obtuse angle, so that the second light-shielding structure 32 and the fourth light-shielding structure 34 can better adapt to the outline of the spacer structure 37 after process formation and cover the spacer structure 37 more fully and effectively. Thus, the light-shielding and protection effect is better.

In an optional embodiment, referring to FIG. 15, the fourth light-shielding structure 34 is in contact with the sidewall of the spacer structure 37 and at least partially covers the sidewall of the spacer structure 37.

This embodiment of the present invention provides a display panel 100. The fourth light-shielding structure 34 is directly attached to the sidewall of the spacer structure 37, so that a larger area of the remaining large viewing angle light can be shielded. Further, the large viewing angle light is fully absorbed, and the halo problem is better alleviated.

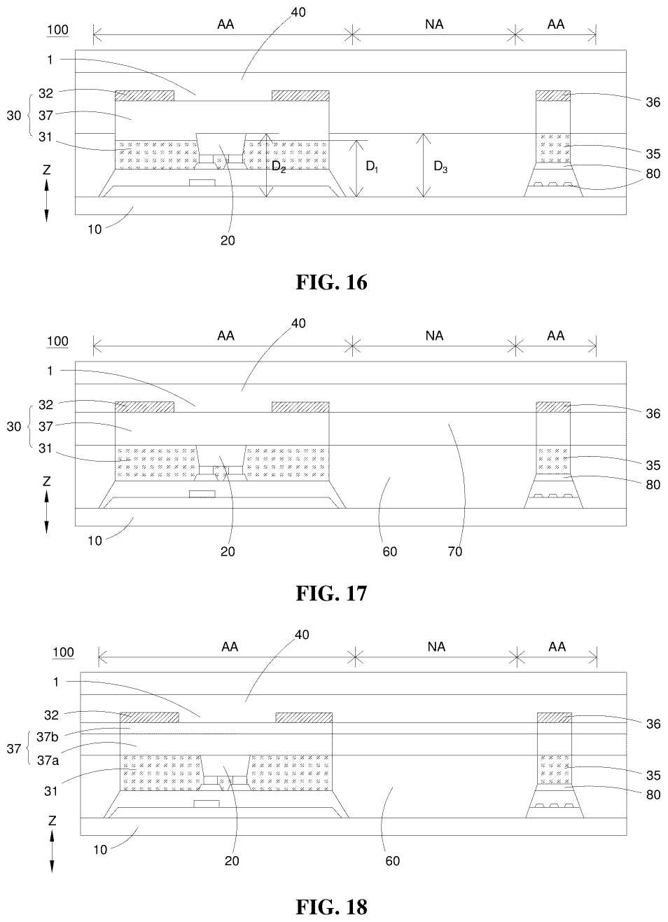

In an optional embodiment, referring to FIG. 16, the distance from the surface of the side of the first light-shielding structure 31 facing away from the substrate 10 to the substrate 10 is D1, and the distance from the surface of the side of the light-emitting element 20 facing away from the substrate 10 to the substrate 10 is D2, where D1≤D2.

When D1=D2, the first light-shielding structure 31 is flush with the light-emitting element 20. The first light-shielding structure 31 fully shields the side of the light-emitting element 20. At the same time, the plane formed by the two is also conducive to bearing the spacer structure 37.

Considering the process accuracy, after the first light-shielding structure 31 is formed, the height of the first light-shielding structure 31 may be lower than the height of the top surface of the light-emitting element 20. However, to shield the light emitted from the side of the light-emitting element 20, the height of the first light-shielding structure 31 needs to be greater than the height of the light-emitting layer in the light-emitting element 20.

To ensure that the light-emitting element 20 emits light effectively, the height of the first light-shielding structure 31 should be prevented from being greater than the height of the light-emitting element 20. Since during the formation process, the first light-shielding structure 31 may overflow to the top surface of the light-emitting element 20, the light emitted from the top surface is shielded. Finally, the display panel 100 is poorly displayed.

This embodiment of the present invention provides a display panel 100. The height of the first light-shielding structure 31 does not exceed the height of the top surface of the light-emitting element 20. On the basis of fully shielding the side of the light-emitting element 20, the actual process accuracy is satisfied. Moreover, when the two are flush, the structure is flatter. It is beneficial to the formation of the spacer structure 37.

In an optional embodiment, the display panel 100 includes a first region AA and a second region NA. The transmittance of the first region AA is less than the transmittance of the second region NA. The light-emitting element 20 and the light control assembly 30 are located in the first region AA.

In an embodiment, in this embodiment, the display panel 100 may be a transparent display screen and specifically includes a first region AA and a second region NA. The first region AA may be a conventional display region. The transmittance of the second region NA is greater than the transmittance of the first region AA. The second region NA may be a transparent region.

It can be seen that the light-emitting element 20 and the light control assembly 30 disposed around the light-emitting element 20 are disposed in the first region AA, so that the light control assembly 30 is used to improve the display light effect of the first region AA. At the same time, a transparent layer structure is disposed in the second region NA, which facilitates the transmission of external light.

This embodiment of the present invention provides a display panel 100. The display panel 100 is divided into the first region AA and the second region NA. The second region NA is used to implement a light-transmissive attribute. At the same time, the light control assembly 30 in the first region AA also alleviates the halo problem of the light-emitting element 20.

In an optional embodiment, the second region NA includes a first filling layer 60. The distance from the surface of the side of the first filling layer 60 facing away from the substrate 10 to the substrate 10 is D3, and the distance from the surface of the side of the first light-shielding structure 31 facing away from the substrate 10 to the substrate 10 is D1, where D3≥D1.

In an embodiment, the first filling layer 60 includes a transparent filling layer. The first filling layer 60 is disposed in the second region NA, so that the second region NA can implement light transmittance to obtain a transparent display screen.

According to the actual process flow, the height of the first filling layer 60 may be controlled to be flush with the first light-shielding structure 31 in the first region AA, so that a flat structure surface can be formed, thereby facilitating the formation of subsequent films.

This embodiment of the present invention provides a display panel 100. The first filling layer 60 is disposed in the second region NA, so that the light-transmissive function of the second region NA is implemented. At the same time, the first filling layer 60 is flush with the first light-shielding structure 31 in the first region AA, so that it is beneficial to the planarization requirement between films, and the formation of the process is facilitated.

In an optional embodiment, referring to FIG. 17, the second region NA includes a second filling layer 70. The second filling layer 70 includes the same material as the spacer structure 37.

Due to the light transmittance and thickness requirement of the second region NA, it is necessary to continue to dispose the second filling layer 70 on the first filling layer 60. The second filling layer 70 also has light transmittance, thereby facilitating the entry of external light.

Since the spacer structure 37 in the first region AA and the second filling layer 70 in the second region NA are disposed on the same layer, and the two are light-transmissive, during the process formation, the two structures may be formed synchronously. The two use transparent adhesive layers. Finally, an integrated structure of the spacer structure 37 and the second filling layer 70 is obtained. Of course, the two may also use different materials, as long as the light transmittance requirements of the two are satisfied.

For the structure of the first functional layer 37a and the second functional layer 37b formed in the spacer structure 37, to synchronize the process of the first region AA and the second region NA, the second filling layer 70 may form an extension film of the first functional layer 37a and the second functional layer 37b. The second filling layer 70 also forms two layers of light-transmissive structures, which is light-transmissive and simplifies the process flow. As shown in FIG. 18, the specific structure and material of the second filling layer 70 are not specifically limited in the present invention, as long as the light transmittance requirement of the second region NA can be satisfied.

This embodiment of the present invention provides a display panel 100. The second filling layer 70 in the second region NA and the spacer structure 37 in the first region AA are made of the same material. Thus, a respective light-transmissive requirement is ensured, and the process flow is simplified, thereby facilitating the integrated formation of the two and improving the preparation efficiency.

In an optional embodiment, referring to FIG. 16, the first region AA includes multiple metal wires 80. The side of the metal wires 80 far away from the substrate 10 includes a fifth light-shielding structure 35. In the first direction Z, the fifth light-shielding structure 35 at least partially overlaps the metal wires 80. The fifth light-shielding structure 35 is on the same layer as the first light-shielding structure 31.

For the multiple metal wires 80 in the first region AA, to prevent external light from directly irradiating the metal wires 80 and causing the impact, in this embodiment, the fifth light-shielding structure 35 is used to cover and shield the metal wires 80, so that the metal wires 80 are shielded and protected.

In an embodiment, multiple metal wires 80 may be disposed on a side of the display panel 100. The metal wires 80 may be RGB data lines, PVDD wires, and PVEE wires. At the same time, the metal wires 80 may be kept on the same layer as the array metal at the bottom of the light-emitting element 20 and may be specifically formed in the same etching process.

In an embodiment, the fifth light-shielding structure 35 and the first light-shielding structure 31 that is also located in the first region AA are disposed on the same layer. During the process formation, first, the first filling layer 60 is formed on the substrate 10 after the bonded light-emitting element 20. As described above, the first filling layer 60 has light-transmissive performance.

Then, the first filling layer 60 is etched around the light-emitting element 20 in the first region AA. At the same time, the first filling layer 60 at a position corresponding to a metal wire 80 is etched, and a groove structure is formed after etching. Then, the first light-shielding structure 31 is filled in the groove, so that the first light-emitting element 20 is disposed around the light-emitting element 20 and absorbs the side light of the light-emitting element 20. The fifth light-shielding structure 35 is filled in the groove corresponding to the metal wire 80 to shield and protect the metal wire 80. It can be seen that the first light-shielding structure 31 and the fifth light-shielding structure 35 are disposed on the same layer.

In an embodiment, according to the actual process flow, the first light-shielding structure 31 and the fifth light-shielding structure 35 are disposed at the same height, so that the first filling layer 60 between the first light-shielding structure 31 and the fifth light-shielding structure 35 is flush with the two to form a flat surface, thereby facilitating subsequent preparation of the spacer structure 37 and the second filling layer 70.

In an embodiment, the first light-shielding structure 31 and the fifth light-shielding structure 35 may use the same black adhesive layer material or different materials. The specific materials of the two are not particularly limited in the present invention as long as the two can play a light-shielding role.

This embodiment of the present invention provides a display panel 100. The fifth light-shielding structure 35 is configured to shield the metal wires 80 to shield and protect the metal wires 80 and prevent external light from being irradiated to the metal wires 80 and causing an adverse effect on the performance. Thus, the panel as a whole has better safety performance.

In an optional embodiment, the display panel 100 includes a sixth light-shielding structure 36 located on the side of the fifth light-shielding structure 35 far away from the substrate 10. The sixth light-shielding structure 36 is on the same layer as the second light-shielding structure 32.

After the preceding preparation process is performed, the spacer structure 37 continues to be disposed on the layer where the first light-shielding structure 31 is located. As described above, the spacer structure 37 may be integrally formed with the second filling layer 70 in the second region NA and may also extend to the fifth light-shielding structure 35 to form a transparent spacer layer.

In the subsequent process, the second light-shielding structure 32 continues to be formed on the spacer structure 37. At the same time, the sixth light-shielding structure 36 continues to be formed on the transparent spacer layer. It can be seen that the second light-shielding structure 32 and the sixth light-shielding structure 36 are disposed on the same layer.

Similarly, the second light-shielding structure 32 and the sixth light-shielding structure 36 may be disposed at an equal thickness to facilitate flushing of the surface. At the same time, the two may also use the same black adhesive material to facilitate the integrated formation. The sixth light-shielding structure 36 can further shield and protect the metal wires 80 at the bottom.

As shown in FIG. 15, for the sixth light-shielding structure 36, similar to the disposition of the fourth light-shielding structure 34, the sixth light-shielding structure 36 may also cover the edge of a transparent film at the bottom. The sixth light-shielding structure 36 is used to shield light emitted from the sidewall of the transparent film to prevent light from being emitted from an edge of the transparent film, thereby further alleviating a halo phenomenon.

Since the light emitted by the light-emitting element 20 can be refracted or reflected multiple times between films, the sixth light-shielding structure 36 further shields and protects the metal wires 80, and at the same time, the sixth light-shielding structure 36 can also shield the side light at a large viewing angle of the light-emitting element 20. The sixth light-shielding structure 36 can also shield part of the light. It is to be understood that the sixth light-shielding structure 36 is a supplementary light-shielding structure for the second light-shielding structure 32, thereby further alleviating a halo phenomenon.

Of course, according to actual requirements, the disposition of the sixth light-shielding structure 36 may also be canceled, and a transparent material is used. Only the fifth light-shielding structure 35 is used to shield and protect the metal wires 80. This is not limited in the present invention.

This embodiment of the present invention provides a display panel 100. The sixth light-shielding structure 36 is further disposed on the fifth light-shielding structure 35, so that the metal wires 80 are double-shielded and double-protected, and external light at the metal wires 80 is fully absorbed. Thus, there is higher security performance.

In an optional embodiment, in the first direction Z, the thickness of the first light-shielding structure 31 is h1, the thickness of the second light-shielding structure 32 is h2, and the thickness of the spacer structure 37 is h3, where h1>h2, and/or, h3>h2.

A total reflection critical angle θ refers to an angle of incidence when total reflection of light occurs at a critical surface. At this time, all light is reflected without refraction. Thus, the light greater than the total reflection critical angle θ may generally undergo total reflection, thereby causing a halo phenomenon. In the present invention, the second light-shielding structure 32 is used to shield the light greater than the total reflection critical angle θ, thereby alleviating a halo. The light less than the total reflection critical angle θ enters the first opening 1 and emits from the first opening 1.

For the value of the total reflection critical angle θ, the specific formula is:

$$θ = arc sin ( {n}_{2} / {n}_{1} )$$

n2 denotes the refractive index of a lower-density medium at the critical surface. n1 denotes the refractive index of a higher-density medium at the critical surface. Thus, after the material at the critical surface is known, the total reflection critical angle θ of light at the critical surface may be known and may be understood as a constant. As can be seen from the preceding analysis, the size of the first opening 1 in the second light-shielding structure 32 is related to the total reflection critical angle θ.

For the size of the first opening 1 in the second light-shielding structure 32, the first opening 1 has a value range requirement. The specific requirement is as follows. The length of the first opening 1 is set to L, and the width of the first opening 1 is set to W. The length of the light-emitting element 20 corresponding to the first opening 1 is set to L₁, and the width of the light-emitting element 20 is set to W₁. Description is given by using an example in which the value range of the width W of the first opening 1 is calculated.

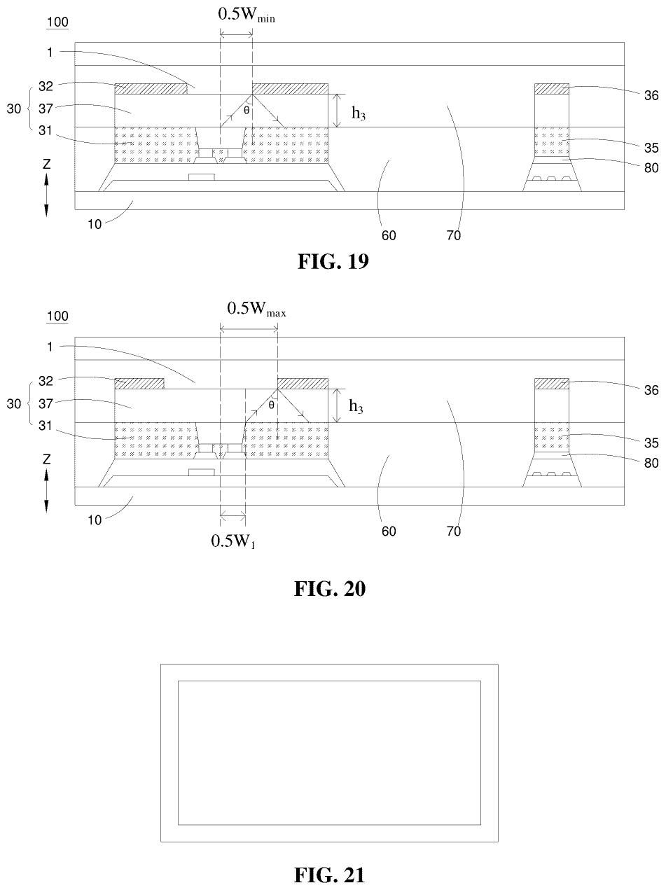

The light at the center of the light-emitting element 20 determines the minimum value Wₘᵢₙ of the width W of the first opening 1. As shown in FIG. 19, the total reflection critical angle when the light is emitted to the critical surface is θ. Thus, the following is obtained according to a geometric relationship:

$$0.5 {W}_{min} / {h}_{3} = tan θ$$

It can be seen that

$${W}_{min} = 2 {h}_{3} \times tan θ$$

The light at the edge of the light-emitting element 20 determines the maximum value Wₘₐₓ of the width W of the first opening 1. The total reflection critical angle when the light is emitted to the critical surface is also θ, as shown in FIG. 20. Thus, the following is also obtained according to a geometric relationship:

$$( 0.5 {W}_{max} - 0.5 {W}_{1} ) / {h}_{3} = tan θ$$

It can be seen that

$${W}_{max} = 2 {h}_{3} \times tan θ + {W}_{1}$$

In summary, it can be seen that the value range of the width W of the first opening 1 is:

$$2 {h}_{3} \times tan θ \leq W \leq 2 {h}_{3} \times tan θ + {W}_{1}$$

Similarly, the value range of the length L of the first opening 1 that can be obtained is:

$$2 {h}_{3} \times tan θ \leq L \leq 2 {h}_{3} \times tan θ + {L}_{1}$$

The thickness h₃ of the spacer structure 37 is usually set to 2 μm to 20 μm. The value may be determined according to actual requirements. The thickness is substituted into the preceding formula, so that the size range of the first opening 1 may be obtained.

The minimum value in this range means that the second light-shielding structure 32 can shield the total reflected light at all positions of the light-emitting element 20, and only light that does not undergo total reflection in the middle of the light-emitting element 20 is allowed to pass through. Although a halo is sufficiently alleviated, the brightness attenuation is relatively great at a large viewing angle. The maximum value means that the second light-shielding structure 32 only shields the total reflected light at the edge of the light-emitting element 20, and the total reflected light at the remaining positions of the light-emitting element 20 may still be partially emitted. Although the brightness at the large viewing angle is relatively high, the halo alleviation is not sufficient.

The smaller the length and the width of the first opening 1 in the preceding value range are, the less a halo phenomenon is, but at the same time, the more the brightness loss at the large viewing angle is. Thus, according to actual requirements, the relationship between a halo and large viewing angle brightness needs to be balanced, and a proper size of the first opening 1 needs to be selected.

In an embodiment, the thickness h₂ of the second light-shielding structure 32 is usually set to 0.5 μm to 10 μm and may be determined according to actual light-shielding requirements.

This embodiment of the present invention provides a display panel 100. The specific size of each part in the light control assembly 30 is defined. When large viewing angle light is effectively shielded to alleviate a halo, the amount of light emitted from the first opening 1 can be balanced. Thus, the brightness loss at the large viewing angle is reduced, the requirement for the display brightness is ensured, and the display effect is better.

As shown in FIG. 21, an embodiment of the present invention provides a display device. The display device includes the display panel 100 described above.

In an embodiment, the display device may be a small-sized wearable display product such as a smart watch or a smart bracelet, a small-to-medium-sized mobile phone or a display or an in-vehicle display product, a large-sized display screen such as a large billboard, and an ultra large-sized display screen. The in-vehicle display mainly includes a part such as meter display, central control display, head-up display, a digital rearview mirror, and in-vehicle entertainment display.

In the display panel and the display device provided by the embodiments of the present invention, the light control assembly is disposed around the light-emitting element. The first light-shielding structure in the light control assembly is disposed around the light-emitting element so that the light emitted from the side of the light-emitting element is absorbed. At the same time, the spacer structure in the light control assembly is disposed on the first light-shielding structure, and the second light-shielding structure is disposed on the spacer structure. The spacing structure is used to raise the second light-shielding structure, so that the second light-shielding structure absorbs the light emitted from the light-emitting element at the large viewing angle. The first opening in the second light-shielding structure corresponds to the light-emitting element to ensure that the light at the positive viewing angle is emitted from the first opening. In this manner, the first light-shielding structure may be used to absorb the side light of the light-emitting element, and the spacer structure may be used to raise the second light-shielding structure so that the second light-shielding structure absorbs the large viewing angle light from the top surface of the light-emitting element. Thus, the halo phenomenon caused by the large viewing angle light of the light-emitting element around the light-emitting element is alleviated, the blurry display is avoided, and the display effect is improved. At the same time, the spacing structure is used to raise the second light-shielding structure. It is beneficial to the formation of the process, and a light-shielding structure is prevented from shielding the top surface of the light-emitting element during the process, thereby facilitating the preparation of the light control assembly.

Although the present invention has been described with reference to preferred embodiments, various modifications may be made thereto, and components therein may be replaced with equivalents without departing from the scope of the present invention. In particular, the various technical features mentioned in the various embodiments may be combined in any manner as long as there is no structural conflict. The present invention is not limited to the specific embodiments disclosed herein but includes all technical aspects falling within the scope of the claims.

What is claimed is:

1. A display panel, comprising:
a substrate;
a light-emitting element located on a side of the substrate; and
a light control assembly, wherein the light control assembly and the light-emitting element are located on a same side of the substrate, the light control assembly comprises a first light-shielding structure, a spacer structure, and a second light-shielding structure which are stacked, at least part of the first light-shielding structure surrounds the light-emitting element, the spacer structure is located on a side of the first light-shielding structure facing away from the substrate, the second light-shielding structure is located on a side of the spacer structure facing away from the first light-shielding structure, and in a first direction, a maximum distance from the second light-shielding structure to the substrate is greater than or equal to a maximum distance from the light-emitting element to the substrate; and
wherein the second light-shielding structure comprises a first opening, the first opening at least partially overlaps the light-emitting element in the first direction, and the first direction is perpendicular to a plane where the substrate is located.

2. The display panel according to claim 1, further comprising a light guide layer located on a side of the second light-shielding structure facing away from the spacer structure, wherein at least part of the light guide layer is filled in the first opening.

3. The display panel according to claim 2, wherein the spacer structure comprises a first functional layer, and in the first direction, the first functional layer covers the light-emitting element.

4. The display panel according to claim 2, wherein the spacer structure comprises a second functional layer, the second functional layer comprises a second opening, at least part of the second opening overlaps the light-emitting element in the first direction, and at least part of the light guide layer is filled in the second opening; and
a refractive index of the light guide layer is n1, and a refractive index of the second functional layer is n2, wherein |n1-n2|>0.

5. The display panel according to claim 4, wherein in a second direction, a width of the second opening gradually increases, the second direction is a direction in which the spacer structure points to the second light-shielding structure, and the width of the second opening is a size of the second opening in a direction parallel to a plane where the display panel is located, or
wherein the display panel satisfies at least one of: in the first direction, the first opening covers the second opening; or
in the first direction, the second opening covers the light-emitting element.

6. The display panel according to claim 1, wherein the spacer structure comprises a first functional layer and a second functional layer, and in the first direction, the first functional layer covers the light-emitting element; and
in the first direction, the second functional layer is located on a side of the first functional layer far away from the first light-shielding structure, a third light-shielding structure is located between the first functional layer and the second functional layer, and in the first direction, at least part of the light-emitting element does not overlap the third light-shielding structure.

7. The display panel according to claim 6, wherein in a direction parallel to a plane where the display panel is located, a minimum distance from the third light-shielding structure to the light-emitting element is less than a minimum distance from the second light-shielding structure to the light-emitting element.

8. The display panel according to claim 6, wherein the display panel satisfies at least one of: in the first direction, a thickness of the first functional layer is greater than a thickness of the second functional layer; or
in the first direction, a thickness of the third light-shielding structure is greater than a thickness of the second light-shielding structure,

9. The display panel according to claim 1, comprising a color conversion structure located on a side of the second light-shielding structure far away from the light-emitting element, wherein the color conversion structure comprises a plurality of color conversion units, and in the first direction, one of the plurality of color conversion units overlaps at least one light-emitting element.

10. The display panel according to claim 1, wherein in a direction parallel to a plane where the display panel is located, a third functional layer is located between the first light-shielding structure and the light-emitting element.

11. The display panel according to claim 1, wherein in the first direction, a first inorganic layer is located between the light-emitting element and the substrate, and a first organic layer is located between the first inorganic layer and the first light-shielding structure; and
in the first direction, a maximum distance from the first organic layer to the substrate is less than a minimum distance from a light-emitting layer of the light-emitting element to the substrate.

12. The display panel according to claim 1, comprising a fourth light-shielding structure at least partially overlapping the spacer structure in a direction parallel to a plane where the display panel is located,
wherein the display panel satisfies at least one of: the second light-shielding structure is in contact with and connected to the fourth light-shielding structure; or
an included angle between a surface of the second light-shielding structure facing the light-emitting element and a surface of the fourth light-shielding structure facing the light-emitting element is greater than or equal to 90°.

13. The display panel according to claim 12, wherein the fourth light-shielding structure is in contact with a sidewall of the spacer structure and at least part of the fourth light-shielding structure covers the sidewall of the spacer structure.

14. The display panel according to claim 1, wherein a distance from a surface of the side of the first light-shielding structure facing away from the substrate to the substrate is D1, and a distance from a surface of a side of the light-emitting element facing away from the substrate to the substrate is D2, wherein D1≤D2.

15. The display panel according to claim 1, comprising a first region and a second region, wherein transmittance of the first region is less than transmittance of the second region, and the light-emitting element and the light control assembly are located in the first region.

16. The display panel according to claim 15, wherein the second region comprises a first filling layer, a distance from a surface of a side of the first filling layer facing away from the substrate to the substrate is D3, and a distance from a surface of the side of the first light-shielding structure facing away from the substrate to the substrate is D1, wherein D3≥D1.

17. The display panel according to claim 15, wherein the second region comprises a second filling layer, and the second filling layer is made of a same material as the spacer structure.

18. The display panel according to claim 15, wherein the first region comprises a plurality of metal wires, a fifth light-shielding structure is located on a side of the plurality of metal wires far away from the substrate, and in the first direction, at least part of the fifth light-shielding structure overlaps the plurality of metal wires; and the fifth light-shielding structure is located on a same layer as the first light-shielding structure,
wherein the display panel comprises a sixth light-shielding structure located on a side of the fifth light-shielding structure far away from the substrate, wherein the sixth light-shielding structure is on a same layer as the second light-shielding structure.

19. The display panel according to claim 1, wherein in the first direction, a thickness of the first light-shielding structure is h1, a thickness of the second light-shielding structure is h2, and a thickness of the spacer structure is h3, wherein the display panel satisfies at least one of: h1>h2, or h3>h2.

20. A display device, comprising a display panel,
wherein the display panel comprises:
a substrate;
a light-emitting element located on a side of the substrate; and
a light control assembly, wherein the light control assembly and the light-emitting element are located on a same side of the substrate, the light control assembly comprises a first light-shielding structure, a spacer structure, and a second light-shielding structure which are stacked, at least part of the first light-shielding structure surrounds the light-emitting element, the spacer structure is located on a side of the first light-shielding structure facing away from the substrate, the second light-shielding structure is located on a side of the spacer structure facing away from the first light-shielding structure, and in a first direction, a maximum distance from the second light-shielding structure to the substrate is greater than or equal to a maximum distance from the light-emitting element to the substrate; and
wherein the second light-shielding structure comprises a first opening, the first opening at least partially overlaps the light-emitting element in the first direction, and the first direction is perpendicular to a plane where the substrate is located.
